(19) United States
(12) Patent Application Publication
(10) Pub. No.: US 2026/0101790 A1
(43) Pub. Date: Apr. 9, 2026

(54) FLIP-CHIP PACKAGE STRUCTURE

(71) Applicant: SILICONWARE PRECISION INDUSTRIES CO., LTD., Taichung City (TW)

(72) Inventors: Tze-Wei SU, Taichung City (TW); Chih-Chun YANG, Taichung City (TW); Yung-Hung CHAN, Taichung City (TW); Yu-Min LO, Taichung City (TW); Mu-Hsuan CHAN, Taichung City (TW)

(21) Appl. No.: 19/054,039

(22) Filed: Feb. 14, 2025

(30) Foreign Application Priority Data
Aug. 28, 2024 (TW) 113132412

(51) Int. Cl. H01L 23/00; H01L 23/498

(52) U.S. Cl. CPC H10W 70/69; H10W 72/287; H10W 90/724

(57) ABSTRACT

A flip-chip package structure including a semiconductor chip and a carrier having a plurality of electrical connection pads is provided, in which the semiconductor chip is connected to second solders on the electrical connection pads of the carrier via first solders. The thickness of the insulating protective layer on the surface of the carrier changes according to the thickness of the first solder, the thickness of the second solder and the thickness of the electrical connection pad, so that it has a certain thickness to avoid bridging problems in the solders, and can also avoid problems with holes in the solders caused by excessive thickness.

### CROSS-REFERENCE TO RELATED APPLICATIONS

The present application is based upon and claims the right of priority to TW Patent Application No. 113132412, filed Aug. 28, 2024, the disclosure of which is hereby incorporated by reference herein in its entirety for all purposes

### BACKGROUND

### 1. Technical Field

The present disclosure relates to a semiconductor packaging structure, and more particularly, to a flip-chip package structure.

### 2. Description of Related Art

Flip-chip ball grid array (FCBGA) semiconductor package is a package in which the active surface of the chip is electrically connected to one surface of the substrate via a plurality of solders, wherein a plurality of solder balls serving as input/output (I/O) terminals are placed on the other surface of the substrate. This semiconductor package can greatly reduce the size, while eliminating the traditional wire design, so that the impedance can be reduced and the electrical properties can be improved to avoid signal degradation during transmission. Therefore, it has indeed become the mainstream packaging technology for the next generation of chips.

However, as shown in FIG. 1A, if the height of a dielectric layer 110 on the surface of a substrate 11 of a semiconductor package 1 is designed to be too low, overflow of a solder 13 may occur, causing the problem of electrical bridging S between adjacent solders; in contrast, as shown in FIG. 1B, if the height of the dielectric layer 110 on the surface of the substrate 11 of the semiconductor package 1 is designed to be too high, a hole V will be formed between the solder 13 and the sidewall of the opening of the dielectric layer 110.

Therefore, how to overcome the above-mentioned problems of the prior art has become an urgent issue to be solved.

### SUMMARY

In view of the various deficiencies of the prior art, the present disclosure provides a flip-chip package structure, which comprises: a carrier including: a body; a plurality of electrical connection pads formed on one surface of the body; and an insulating protective layer formed on the surface of the body and the plurality of electrical connection pads, wherein the plurality of electrical connection pads are exposed from the insulating protective layer; and an electronic element having an active surface and an inactive surface opposite to the active surface, wherein a plurality of first solders are disposed on the active surface, and a plurality of second solders are disposed on the plurality of electrical connection pads of the carrier, so that the electronic element is connected to the plurality of second solders on the carrier via the plurality of first solders, wherein a thickness of the insulating protective layer of the carrier is H and meets following conditions: [(a+b)×0.4]+c≤H≤[(a+b)×0.6]+c, and a thickness of each of the first solders is a, a thickness of each of the second solders is b, and a thickness of each of the electrical connection pads is c.

In the aforementioned flip-chip package structure, a plurality of conductive bumps are disposed on the active surface, and the plurality of first solders are disposed on the plurality of conductive bumps.

In the aforementioned flip-chip package structure, the body is provided with a circuit layer.

In the aforementioned flip-chip package structure, the plurality of electrical connection pads are electrically connected to the circuit layer.

In the aforementioned flip-chip package structure, the carrier is a substrate, a circuit structure, or an interposer.

Through the implementation of the present disclosure, the thickness of the insulating protective layer of the carrier is changed according to the thickness of the first solder on the electronic element end, the thickness of the second solder on the carrier end and the thickness of the electrical connection pad on the carrier, so that it has a certain thickness to serve as a barrier wall to avoid bridging problems of adjacent solders, and at the same time, it can also avoid the problem of holes in the solder caused by excessive thickness. In addition, the flip-chip package structure can solve the industry's existing technical problems without adding new development processes and materials or purchasing machines, so there will be no large additional costs. Furthermore, the flip-chip package structure of the present disclosure can solve conventional problems without adding or removing elements, and has high customer and market acceptance.

### BRIEF DESCRIPTION OF THE DRAWINGS

FIG. 1A and FIG. 1B are schematic cross-sectional views of a conventional flip-chip ball grid array semiconductor package.

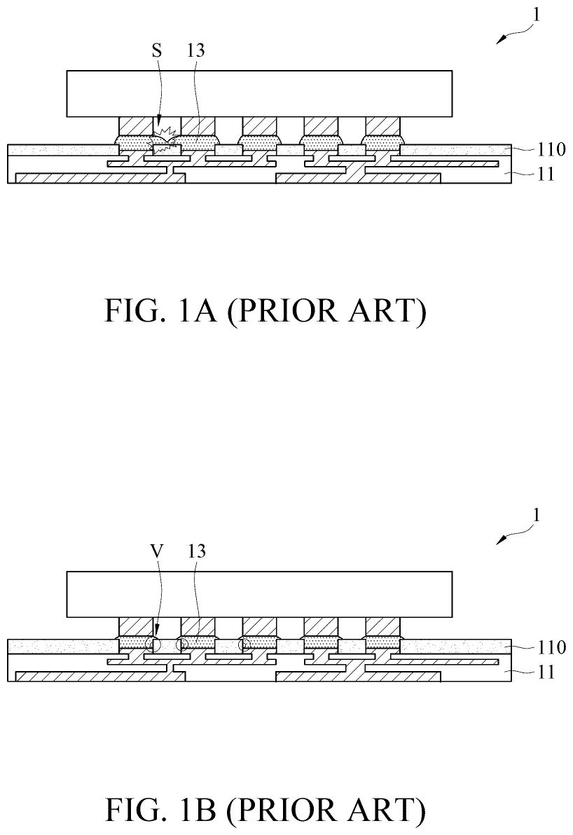

FIG. 2 is a schematic cross-sectional view of a flip-chip package structure of the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

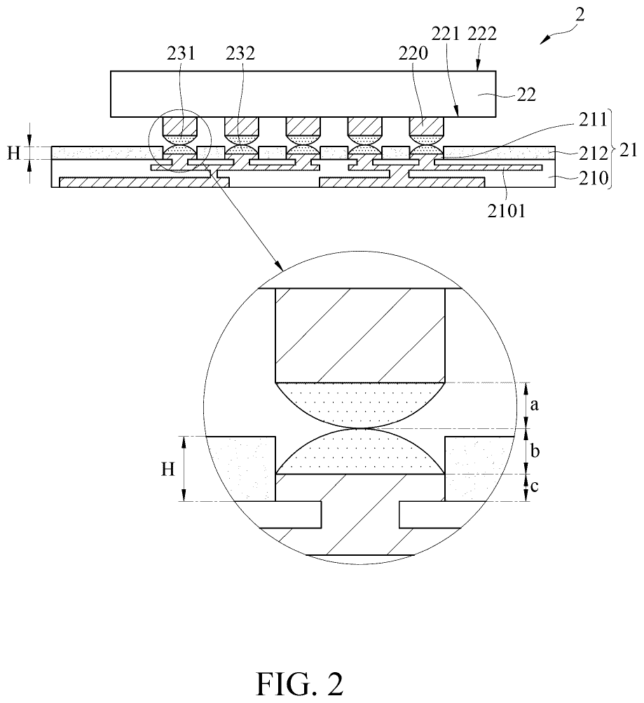

FIG. 2 is a schematic cross-sectional view of a flip-chip package structure 2 of the present disclosure. The flip-chip package structure 2 includes a carrier 21 and an electronic element 22, wherein the electronic element 22 is connected to and electrically connected to the carrier 21 in a flip-chip manner.

The carrier 21 is, for example, a substrate with a core layer and a circuit structure or a circuit structure without a core layer. In the circuit structure, a circuit layer, such as a redistribution layer (RDL), is formed on the dielectric material. In addition, the carrier 21 can also be an interposer.

In one embodiment, the carrier 21 includes a body 210; a plurality of electrical connection pads 211 formed on a surface of the body 210; and an insulating protective layer 212 formed on the surface of the body 210 and the plurality of electrical connection pads 211, wherein the plurality of electrical connection pads 211 are exposed from the insulating protective layer 212.

The body 210 is provided with a circuit layer 2101, and the plurality of electrical connection pads 211 are electrically connected to the circuit layer 2101, and the insulating protective layer 212 is made of, for example, dielectric material, solder mask, ink, or solder-resist material.

The electronic element 22 is connected to the carrier 21 and is electrically connected to the plurality of electrical connection pads 211. The electronic element 22 may be an active element, a passive element, or a combination of the active element and the passive element. The active element may be an application processor (AP) used in mobile devices such as mobile phones or other semiconductor chips such as computing chips, while the passive element may be a resistor, a capacitor, or an inductor.

In one embodiment, the electronic element 22 is a semiconductor chip and has an active surface 221 and an inactive surface 222 opposite to the active surface 221, wherein a plurality of conductive bumps 220 are disposed on the active surface 221. The conductive bumps 220 are, for example, copper pillars.

When the electronic element 22 is connected to the carrier 21 in a flip-chip manner, a plurality of first solders 231 are mainly disposed on the plurality of conductive bumps 220 of the electronic element 22, and a plurality of second solders 232 are disposed on the plurality of electrical connection pads 211 of the carrier 21, so that the electronic element 22 is connected to the second solders 232 of the carrier 21 via the first solders 231.

In one embodiment, the thickness of each of the first solders 231 is a, the thickness of each of the second solders 232 is b, the thickness of each of the electrical connection pads 211 is c, then the thickness H of the insulating protective layer 212 disposed on the body 210 of the carrier 21 must meet the following conditions: [(a+b)×0.4]+c≤H≤[(a+b)×0.6]+c to make the thickness H of the insulating protective layer 212 moderate to avoid problems of being too low or too high.

Therefore, in the flip-chip package structure of the present disclosure, the thickness of the insulating protective layer of the carrier is changed according to the thickness of the first solder on the electronic element end, the thickness of the second solder on the carrier end and the thickness of the electrical connection pad on the carrier, so that it has a certain thickness according to the actual situation to serve as a barrier wall to avoid bridging problems of adjacent solders, and at the same time, it can also avoid the problem of holes in the solder caused by excessive thickness.

In addition, the flip-chip package structure can solve the industry's existing technical problems without adding new development processes and materials or purchasing machines, so there will be no large additional costs. Furthermore, the flip-chip package structure of the present disclosure can solve conventional problems without adding or removing elements, and has high customer and market acceptance.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A flip-chip package structure, comprising:
a carrier including:
a body;
a plurality of electrical connection pads formed on one surface of the body; and
an insulating protective layer formed on the surface of the body and the plurality of electrical connection pads, wherein the plurality of electrical connection pads are exposed from the insulating protective layer; and
an electronic element having an active surface and an inactive surface opposite to the active surface, wherein a plurality of first solders are disposed on the active surface, and a plurality of second solders are disposed on the plurality of electrical connection pads of the carrier, so that the electronic element is connected to the plurality of second solders on the carrier via the plurality of first solders,
wherein a thickness of the insulating protective layer of the carrier is H and meets following conditions: [(a+b)×0.4]+c≤H≤[(a+b)×0.6]+c, and a thickness of each of the first solders is a, a thickness of each of the second solders is b, and a thickness of each of the electrical connection pads is c.

2. The flip-chip package structure of claim 1, wherein a plurality of conductive bumps are disposed on the active surface, and the plurality of first solders are disposed on the plurality of conductive bumps.

3. The flip-chip package structure of claim 1, wherein the body is provided with a circuit layer.

4. The flip-chip package structure of claim 3, wherein the plurality of electrical connection pads are electrically connected to the circuit layer.

5. The flip-chip package structure of claim 1, wherein the carrier is a substrate, a circuit structure, or an interposer.
